(19) United States
(12) Patent Application Publication
(10) Pub. No.: US 2020/0272047 A1
(43) Pub. Date: Aug. 27, 2020

(54) METHOD OF FORMING CNT-BNNT NANOCOMPOSITE PELLICLE

(71) Applicant: Applied Materials, Inc., Santa Clara, CA (US)

(72) Inventors: Sukti CHATTERJEE, San Jose, CA (US); Yuriy MELNIK, San Jose, CA (US); Pravin K. NARWANKAR, Sunnyvale, CA (US)

(73) Assignee: Applied Materials, Inc., Santa Clara, CA (US)

(21) Appl. No.: 16/405,330

(22) Filed: May 7, 2019

Related U.S. Application Data
(60) Provisional application No. 62/809,425, filed on Feb. 22, 2019.

(51) Int. Cl. G03F 1/62; C01B 32/168; C01B 32/162; C01B 21/064; B01J 23/755; B01J 23/745

(52) U.S. Cl. CPC G03F 1/62; C01B 32/168; C01B 32/162; C01P 2004/13; B01J 23/755; B01J 23/745; C01B 2202/08; C01B 21/0648

(57) ABSTRACT

Embodiments of the present disclosure generally relate to nanocomposite pellicles for extreme ultraviolet lithography systems. A pellicle comprises a plurality of carbon nanotubes arranged in a planar sheet formed from a plurality of metal catalyst droplets. The plurality of carbon nanotubes are coated in a first conformal layer of boron nitride. The pellicle may comprise a plurality of boron nitride nanotubes formed simultaneously as the first conformal layer of boron nitride. The pellicle may comprise a carbon nanotube coating disposed on the first conformal layer of boron nitride and a second conformal layer of boron nitride or boron nitride nanotubes disposed on the carbon nanotube coating. The pellicle is UV transparent and is non-reactive in hydrogen radical environments.

### CROSS-REFERENCE TO RELATED APPLICATIONS

This application claims the benefit of U.S. Provisional Patent Application Ser. No. 62/809,425, filed Feb. 22, 2019, which is herein incorporated by reference.

### BACKGROUND

### Field

Embodiments of the present disclosure generally relate to nanocomposite pellicles for extreme ultraviolet (EUV) lithography systems.

### Description of the Related Art

During photolithography, EUV light may be utilized to transfer a pattern on a photomask to a substrate. While performing the photolithography process, a pellicle is used to protect the photomask from particle contamination and damage. A pellicle is a thin transparent membrane which allows lights and radiation to pass therethrough to the photomask and that does not affect the pattern generated by the EUV light passing through the photomask. The pellicle is disposed above the mask such that the pellicle does not touch the surface of the mask to prevent particles from collecting on the mask, which may adversely affect the lithography process. Pellicles provide a functional and economic solution to particulate contamination by mechanically separating particles from the mask surface.

When exposing a substrate in a EUV lithography system, hydrogen may freely flow in the chamber. The ultraviolet (UV) light used to expose substrates in EUV lithography systems is so intense that the UV light may create hydrogen radicals from the hydrogen in the chamber. Hydrogen radicals are highly reactive in terms of chemical reactivity and may etch the pellicle disposed above the mask. Typically, pellicles are comprised of silicon membrane or carbon nanotubes (CNTs). However, both silicon membranes and CNTs are susceptible to being etched by hydrogen radicals.

Therefore, there is a need in the art for pellicles that are not susceptible to being etched by hydrogen radicals when exposing a substrate to EUV light in EUV lithography systems.

### SUMMARY

Embodiments of the present disclosure generally relate to nanocomposite pellicles for EUV lithography systems. A pellicle comprises a plurality of carbon nanotubes arranged in a planar sheet formed from a plurality of metal catalyst droplets. The plurality of carbon nanotubes are coated in a first conformal layer of boron nitride. The pellicle may comprise a plurality of boron nitride nanotubes formed simultaneously as the first conformal layer of boron nitride. The pellicle may comprise a carbon nanotube coating disposed on the first conformal layer of boron nitride and a second conformal layer of boron nitride or boron nitride nanotubes disposed on the carbon nanotube coating. The pellicle is UV transparent and is non-reactive in hydrogen radical environments.

In one embodiment, a pellicle for an extreme ultraviolet lithography system comprises a plurality of carbon nanotubes arranged in a planar sheet and a first boron nitride coating disposed on each of the plurality of carbon nanotubes.

In another embodiment, a method of forming pellicle comprises forming a plurality of carbon nanotubes arranged in a planar sheet, coating the plurality of carbon nanotubes with boron nitride, and forming a plurality of boron nitride nanotubes. The plurality of boron nitride nanotubes are formed simultaneously as the plurality of carbon nanotubes are coated with boron nitride.

In yet another embodiment, a method of forming pellicle comprises forming a plurality of carbon nanotubes arranged in a planar sheet, coating the plurality of carbon nanotubes with a first layer of boron nitride, coating the first layer of boron nitride with a carbon nanotube layer, and coating the carbon nanotube layer with a second layer of boron nitride.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a schematic cross-sectional view of a lithography system, such as an extreme ultraviolet lithography system, according to an embodiment of the disclosure.

FIGS. 2A-2B an exemplary lithography mask assembly for use in a lithography system, according to one embodiment.

FIGS. 3A-3C illustrate various embodiments of forming a nanocomposite pellicle, according to one embodiment.

FIGS. 4A-4E illustrate various embodiments of forming a nanocomposite multilayer pellicle, according to another embodiment.

FIG. 5 illustrates a tool schematic for forming a nanocomposite pellicle, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to nanocomposite pellicles for EUV lithography systems. A pellicle comprises a plurality of carbon nanotubes arranged in a planar sheet formed from a plurality of metal catalyst droplets. The plurality of carbon nanotubes are coated in a first conformal layer of boron nitride. The pellicle may comprise a plurality of boron nitride nanotubes formed simultaneously as the first conformal layer of boron nitride. The pellicle may comprise a carbon nanotube coating disposed on the first conformal layer of boron nitride and a second conformal layer of boron nitride or boron nitride nanotubes disposed on the carbon nanotube coating. The pellicle is UV transparent and is non-reactive in hydrogen radical environments.

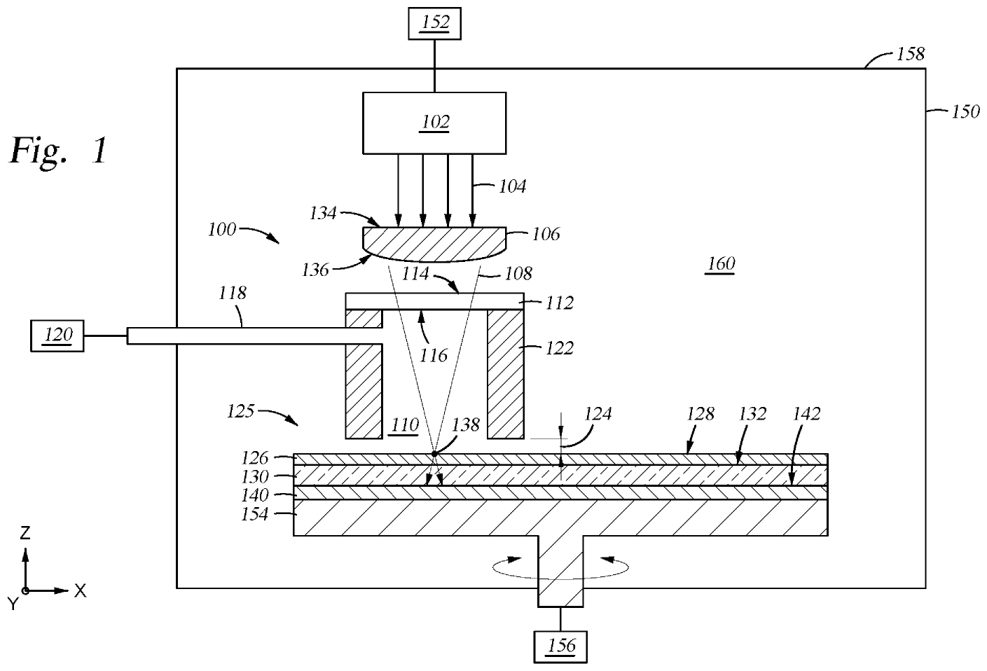

FIG. 1 illustrates a schematic cross-sectional view of a lithography system 100, such as an EUV lithography system, according to an embodiment of the disclosure. A chamber body 150 and lid assembly 158 define a volume 160. In one embodiment, the chamber body 150 and the lid assembly 158 are fabricated from ultraviolet-proof plastic materials. The lithography system 100 is disposed within the volume 160. A pedestal 154 is also disposed within the volume 160. In one embodiment, the pedestal 154 is disposed in the volume 160 opposite the lithography system 100. The pedestal 154 is configured to support a lithography mask 125, such as a photomask, during processing. The mask 125 includes a photomask substrate 130 and one or more films 126 deposited on a surface 132 of the photomask substrate 130 facing the lithography system 100.

The lithography system 100 may optionally include a volume 110 at least partially defined by a transparent window 112 and a sidewall 122 extending from the transparent window 112. In one embodiment, the sidewall 122 is fabricated from an opaque material. In another embodiment, the sidewall 122 is fabricated from a transparent material. Suitable materials for fabrication of the sidewall 122 include metallic materials, such as aluminum, stainless steel, or alloys thereof. The sidewall 122 may also be fabricated from polymeric materials, such as plastic materials or the like.

A UV light source 102, such as a laser or other radiation source, is disposed within the volume 160. A power source 152 is coupled to the UV light source 102 to control electromagnetic energy emitted therefrom. The electromagnetic energy emitted from the UV light source 102 may be in the form of a light beam or a laser beam. The beam travels into the volume 110 along a propagation path 104. In one embodiment, the beam is coherent and collimated. In another embodiment, the beam is spatially and/or temporally decorrelated to attenuate an energy density of the beam. In one embodiment, the UV light source 102 is configured to generate EUV radiation with a wavelength in the range of 5 nm to 20 nm.

The lithography system 100 may optionally include a lens 106. The beam emitted from the UV light source 102 may propagate along the propagation path 104 to a first surface 134 of the lens 106. In one embodiment, the first surface 134 of the lens 106 is substantially planar. In another embodiment, the first surface 134 of the lens 106 is concave or convex. In one embodiment, the lens is positioned in the volume 160 opposite the pedestal 154. The beam may propagate through the lens 106 and exit a second surface 136. In one embodiment, the second surface 136 is concave. In another embodiment, the second surface 136 is convex. While the lens 106 is illustrated as a single lens, the lens 106 may include one or more lenses in series (e.g., a compound lens). The lens 106 may be fabricated from a fused silica material or a quartz material.

The beam emitted from the UV light source 102 may be focused by the lens 106 to form a focused beam 108. A focal point 138 of the focused beam 108 may be positioned at a surface 128 of the film(s) 126. In one embodiment, the focal point 138 is positioned along a central axis of the volume 110. The surface 128 is a surface of the film(s) 126 deposited on the photomask substrate 130. The lens 106 may be coaxial with a central axis of the volume 110.

Upon exiting the surface 136 of the lens 106, the focused beam 108 may travel to a first surface 114 of the transparent window 112. The transparent window 112 may be optionally included, and may be fabricated from a fused silica material or a quartz material. In one embodiment, the transparent window 112 has a thickness of between about 1 mm and about 5 mm, such as about 3 mm. If included in the lithography system 100, the transparent window 112 does not substantially alter the propagation path 104 of the focused beam 108 propagating therethrough. Thus, the focused beam 108 may propagate through the transparent window 112 from the first surface 114 to a second surface 116 of the transparent window 112 without substantial modification or aberration being introduced into the focused beam 108. Both the lens 106 and the transparent window 112 may be optionally included such that the mask 125 is directly exposed to the beam without any protection, as all materials are opaque to EUV wavelength.

The lens 106 may focus the beam such that the energy of the beam is focused at the focal point 138 and is de-focused after the beam propagates through the mask 125. As such, an energy density of the beam may be concentrated at the focal point 138, and the energy density of the beam may be reduced as the beam propagates through the mask 125. In one embodiment, the energy density of the focused beam 108 at the focal point 138 is greater than the energy density of the focused beam 108 at a coating 140 disposed on a surface 142 of the photomask substrate 130 opposite the film(s) 126. That is, the beam is focused from the surface 128 of the film(s) 126 to the surface 132 of the photomask substrate 130 and is defocused at the surface 142 of the photomask substrate 130 where the coating 140 is adhered to the photomask substrate 130. The beam does not etch the photomask substrate 130 because the power of the UV light source 102 is less than a threshold to etch the photomask substrate 130. The beam may be defocused at the surface 142 of the photomask substrate 130 to substantially reduce or prevent modification of the coating 140 at a location where the beam is incident on the surface 142 and the coating 140.

The photomask substrate 130 is disposed on and supported by the pedestal 154. In one embodiment, the pedestal 154 is configured to rotate about a central axis during processing of the mask 125. Alternatively or in addition, the pedestal 154 is configured to move in the X and Y directions to position the mask 125 (or a specific portion thereof) in the path of the focused beam 108. In one embodiment, the pedestal 154 is configured to move in the Z direction to increase or decrease a space 124 between the sidewall 122 and the mask 125. Moving the pedestal 154 in the Z direction also enables changing of the focal point 138 of the focused beam 108 relative to the surface 128 of the film(s) 126 of the mask 125. Accordingly, if the film(s) 126 has a non-uniform thickness, the pedestal 154 may be moved in the Z direction to more finely align the focal point 138 on the surface 128 to improve ablation of the material from the mask 125.

An actuator 156 is coupled to the pedestal 154 to control movement of the pedestal 154 relative to the lithography system 100. The actuator 156 may be a mechanical actuator, an electrical actuator, or a pneumatic actuator or the like which is configured to either rotate the pedestal 154 about the central axis and/or move the pedestal 154 in any of the X, Y, and Z directions. In one embodiment, the lithography system 100 is stationary within the volume 160 while the pedestal 154 is configured to move such that the surface 128 of the mask 125 is positioned at the focal point 138 of the focused beam 108. Alternatively, the lithography system 100 may be movably disposed with the volume 160 while the pedestal 154 remains stationary.

In one embodiment, an exhaust port 118 is formed through the sidewall 122. The exhaust port 118 extends through the chamber body 150. The exhaust port 118 is fluidly connected to an exhaust pump 120 and enables fluid communication between the volume 110 and the exhaust pump 120. The exhaust pump 120 generates a fluid flow path from the volume 110 to the exhaust pump 120 by reducing a pressure in the volume 110 to evacuate particles from the volume 110. That is, a pressure in the volume 110 may be slightly less than an atmospheric pressure external to the volume 110. During processing, the volume 110 may be maintained at a vacuum using the exhaust pump 120 and the exhaust port 118, as processing in a vacuum state reduces the potential for particle contamination.

The sidewall 122 is spaced apart from the film(s) 126 deposited on the photomask substrate 130. The space 124 between the sidewall 122 and the mask 125 enables a fluid to flow between the sidewall 122 and the mask 125 and into the exhaust port 118. The fluid flow from the space 124 to the exhaust port 118 facilitates film particle removal from the volume 110 and prevents or substantially reduces re-deposition of the particles on the mask 125. Together, the sidewall 122, exhaust port 118, and transparent window 112 may form a fume extraction hood that evacuates particles from the volume 110.

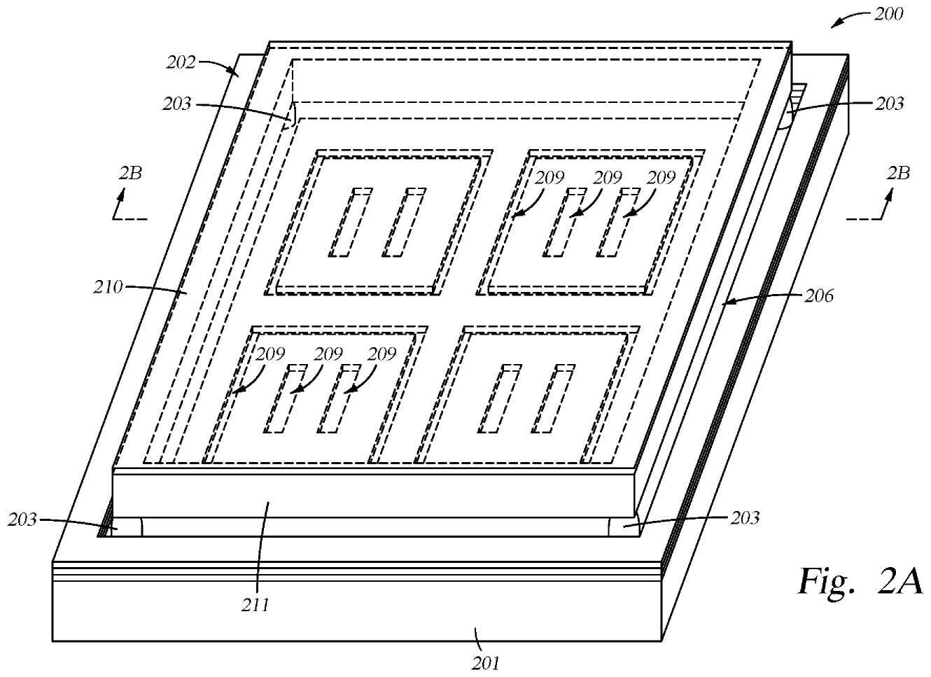

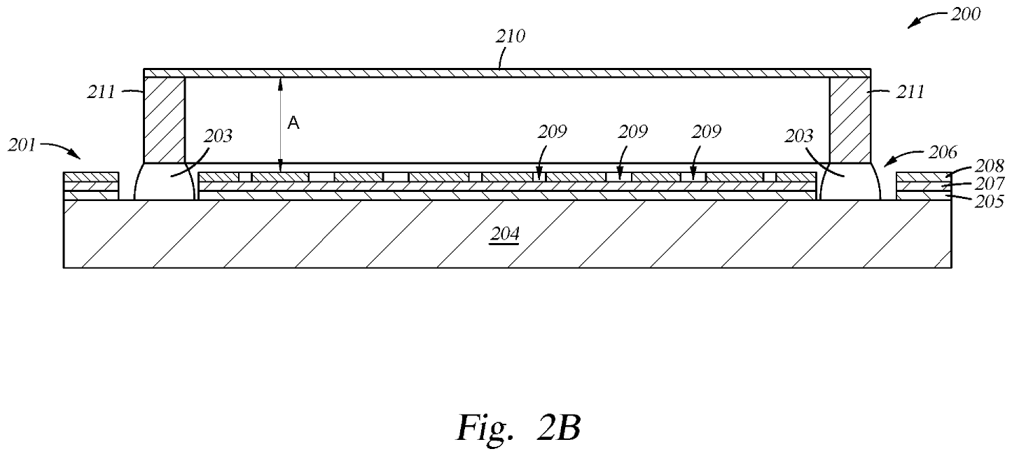

While not shown in FIG. 1, the lithography system 100 may include a pellicle disposed above the mask 125. A pellicle (shown below in FIGS. 2A-2B) is a thin transparent membrane which allows light and radiation to pass therethrough to the photomask and that does not affect the pattern generated by the EUV light passing through the photomask. The pellicle may prevent particles from settling on the mask 125, which may adversely affect the lithography of the films 126.

FIG. 2A is a schematic isometric view of an exemplary lithography mask assembly 200 for use in a lithography system, according to one embodiment. FIG. 2B is a schematic cross-sectional view of the lithography mask assembly 200 in FIG. 2A taken along line 2B-2B. The lithography mask assembly 200 includes a lithography mask 201 and a pellicle 202 secured thereto by a plurality of adhesive patches 203 interposed therebetween. The mask 201 may be the mask 125 of FIG. 1. In some embodiments, the mask 201 is configured for use with an EUV lithography processing system, such as the lithography system 100 of FIG. 1, and features a substrate 204, a reflective multilayer stack 205 disposed on the substrate 204, a capping layer 207 disposed on the reflective multilayer stack 205, and an absorber layer 208 disposed on the capping layer 207. The substrate 204, the reflective multilayer stack 205, the capping layer 207, and the absorber layer 208 may be the one or more films 126 of FIG. 1.

The absorber layer 208 having a plurality of openings 209 formed therethrough forms a patterned surface of the lithography mask 201. The plurality of openings 209 may extend through the absorber layer 208 to expose the capping layer 207 disposed therebeneath. In other embodiments, the plurality of openings 209 may further extend through the capping layer 207 to expose the reflective multilayer stack 205 disposed therebeneath. In some embodiments, the mask 201 comprises one or more blackborder openings 206, i.e., one or more openings extending through the absorber layer 208, the capping layer 207, and the reflective multilayer stack 205.

The pellicle 202 includes a thin (e.g., <30 nm in thickness) transparent pellicle membrane 210 extending across a frame 211 and secured thereto by an adhesive layer (not shown) interposed therebetween. The pellicle membrane 210 is spaced apart from the surface of the mask 201 by a distance A. The pellicle frame 211 may be spaced apart from the surface of the mask 201 by a thickness of the adhesive patches 203 by a distance of less than about 1 mm, such as between about 10 μm and about 500 μm. In one embodiment, the adhesive patches 203 are disposed directly on the surface of the substrate 204. In other embodiments, the adhesive patches 203 are disposed directly on the surface of the reflective multilayer stack 205. In other embodiments, the adhesive patches 203 are disposed directly on the surface of the absorber layer 208.

Spacing of the pellicle membrane 210 from the surface of the mask 201 desirably prevents particles, e.g., dust, which may become collected thereon from being in the field of focus when the pattern of the mask 201 is transferred to a resist film or layer on a workpiece. Spacing the frame 211 from the surface of the mask 201 allows clean gas, e.g., air, to flow between the pellicle 202 and the mask 201. The free flow of gas between the pellicle 202 and the mask 201 may prevent unequal pressures on the opposite surface of the membrane 210 during a vacuum EUV lithography process which may cause the breakage thereof.

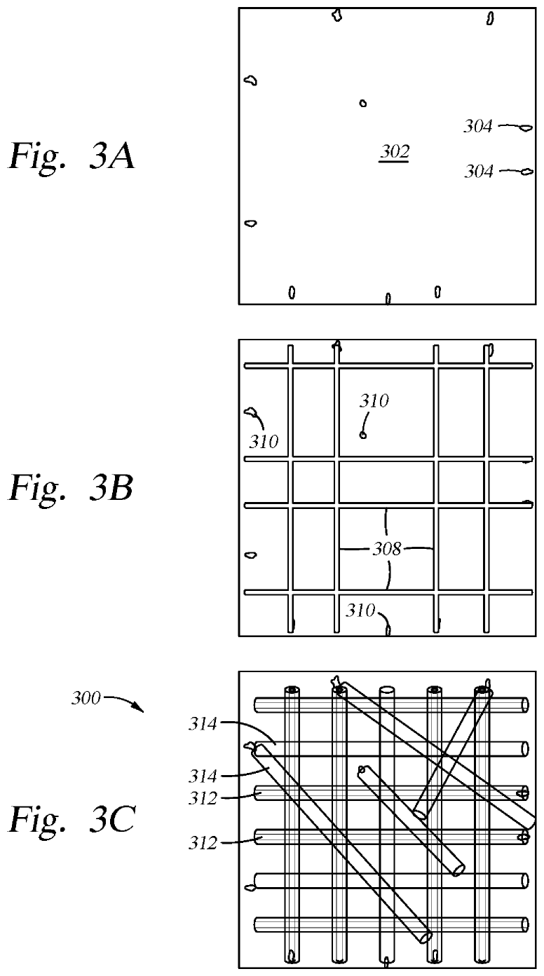

FIGS. 3A-3C illustrate various embodiments of forming a nanocomposite pellicle 300, according to one embodiment. The nanocomposite pellicle 300 may be utilized in an EUV lithography system, such as the lithography system 100 of FIG. 1. The nanocomposite pellicle 300 may be the pellicle 202 of FIGS. 2A-2B.

FIG. 3A illustrates a plurality of metal catalyst droplets 304 or particles being dispersed on a graphene membrane 302. The metal catalyst droplets 304 initiate CNT growth. The metal catalyst droplets 304 may be iron (Fe), nickel (Ni), or NiFe droplets. The dispersion of the metal catalyst droplets 304 may be random or orderly. Each of the metal catalyst droplets 304 may have a diameter of about 10 nm or less. The metal catalyst droplets 304 may be deposited or dispersed by evaporation or physical vapor deposition (PVD). The metal catalyst droplets 304 are able to catalytically decompose gaseous carbon-containing molecules to initiate CNT growth.

FIG. 3B illustrates a plurality of CNTs 308 initiated from the metal catalyst droplets 304. The CNTs 308 form a planar sheet or membrane. The planar sheet of CNTs 308 may have a lattice structure such that each CNT 308 is spaced from an adjacent CNT 308. In embodiments where the metal catalyst droplets 304 are randomly dispersed, the CNTs 308 grow in a random arrangement to form a planar sheet. The planar sheet of CNTs 308 may form any shape, such as square, rectangular, round, or trapezoidal. The CNTs 308 may have a length of about 30 nm and a diameter between about 10 nm to 50 nm.

The CNTs 308 may be synthesized using catalytic chemical vapor deposition (CCVD). Carbon precursor molecules disposed on the surface of the metal catalyst droplets 304 undergo a catalytic decomposition, which is then followed by diffusion of the carbon atoms produced either on the surface or in the metal catalyst droplets 304. The growth temperature, as well as the size of the metal catalyst droplets 304, determines the limit of carbon solubility in the metal catalyst droplets 304. Super-saturation of the metal catalyst droplets 304 results in solid carbon precipitation and the subsequent formation of the CNT 308 structures. After the CNTs 308 are grown, some excess metal catalyst droplets 310 or residue of the metal catalyst droplets 310 may remain uncovered by CNTs 308.

FIG. 3C illustrates the planar sheet of CNTs coated with boron nitride (BN) 312 and BN nanotubes (BNNTs) 314 forming a CNT-BN-BNNT nanocomposite pellicle 300. The coating of BN on the BN coated CNTs 312 may occur simultaneously as the BNNTs 314 grow. The BN coating on the BN coated CNTs 312 may have a thickness of about 2-5 nm. The CNT-BN-BNNT nanocomposite pellicle 300 may have a total thickness of about 30 nm or less and a length and width of about 30 nm. Each BN coated CNT 312 may be spaced from adjacent BN coated CNTs 312 or adjacent BNNTs 314. As such, the pellicle 300 may have spaces or gaps therethrough.

The BNNTs 314 are formed from the residue of the metal catalyst droplets 310 that were not used to initiate CNT growth. The residue or remaining metal catalyst droplets 310 initiate BNNT growth such that the resulting structure includes both BNNTs 314 and the BN coated CNTs 312. Additionally, it should be noted that all CNTs are BN coated CNTs 312 once the BNNTs 314 have been formed. The residue or remaining metal catalyst droplets 310 may have a random dispersion, and as such, the BNNTs 314 initiated from the randomly dispersed excess metal catalyst droplets 310 may have a random arrangement.

The BN coated CNTs 312 and the BNNTs 314 are transparent in UV light, and may have an EUV transmission of about 90% or greater. The pellicle 300 has increased thermomechanical strength, as BN is a ceramic material. As such, the pellicle 300 is non-reactive in a hydrogen radical environment.

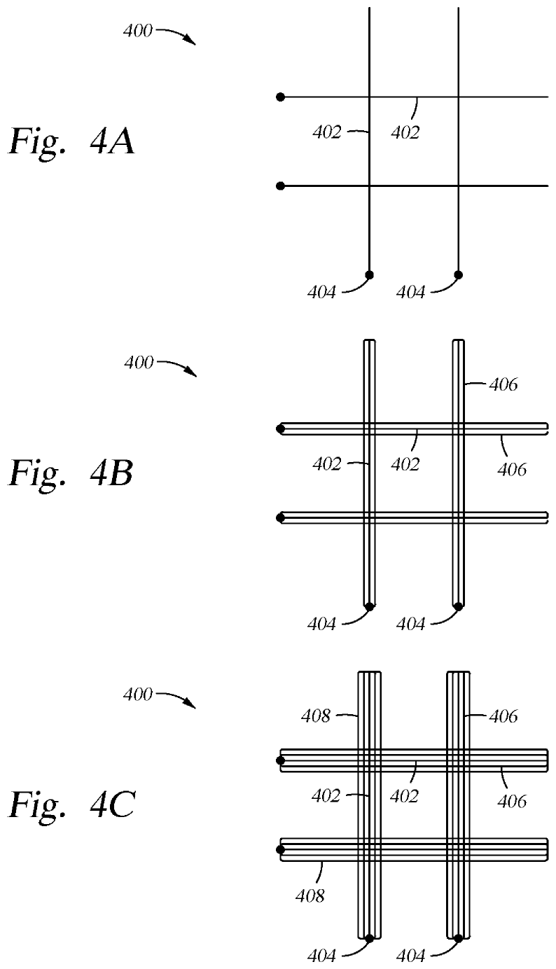

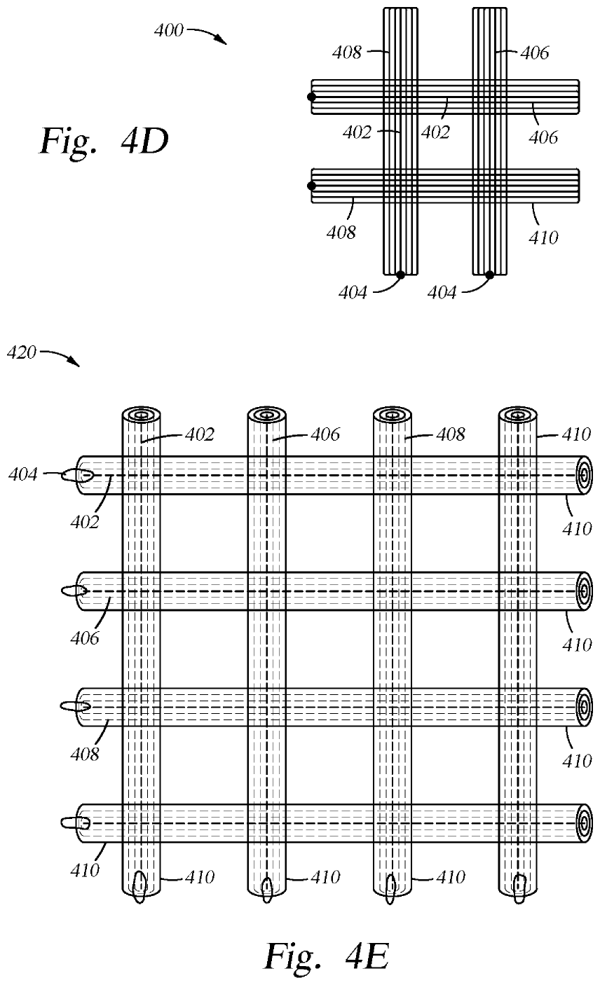

FIGS. 4A-4E illustrate various embodiments of forming a nanocomposite multilayer pellicle 400, according to another embodiment. The multilayer pellicle 400 may be utilized in an EUV lithography system, such as the lithography system 100 of FIG. 1. The multilayer pellicle 400 may be the pellicle 202 of FIGS. 2A-2B.

FIG. 4A illustrates a plurality of CNTs 402 initiated from a plurality of metal catalyst droplets 404 or particles. In one embodiment, the metal catalyst droplets 404 are dispersed in an orderly manner such that the growth of the CNTs 402 is not random. The metal catalyst droplets 404 may be Fe, Ni, or NiFe droplets. Each of the metal catalyst droplets 404 may have a diameter of about 10 nm or less. The metal catalyst droplets 404 may be deposited or dispersed by evaporation or physical vapor deposition (PVD). The metal catalyst droplets 404 are able to catalytically decompose gaseous carbon-containing molecules to initiate CNT 402 growth. The CNTs 402 may be synthesized using CCVD.

The metal catalyst droplets 404 may be dispersed in a particular layout to enable an orderly or evenly spaced layout for the CNTs 402. For example, the metal catalyst droplets 404 may be dispersed a manner that enables the CNTs 402 to form a planar sheet or membrane. The planar sheet of CNTs 402 may have a lattice structure such that each CNT 402 is spaced from an adjacent CNT 402. The planar sheet of CNTs 402 may form any shape, such as square, rectangular, round, or trapezoidal. The CNTs 402 may have a length of about 30 nm and a diameter between about 10 nm to 50 nm. The density of the plurality of CNTs 402 directly correlates to the distribution of the metal catalyst droplets 404. The plurality of CNTs 402 forms the first layer of the pellicle 400.

FIG. 4B illustrates the planar sheet of CNTs 402 having a first conformal coating of BN 406 thereon. The first conformal coating of BN 406 may be hexagonal BN (h-BN). The hexagonal BN 406 has a same or similar lattice structure as the CNTs 402. As such, the growth of the hexagonal BN 406 follows the layout of the CNTs 402. The first conformal coating of h-BN 406 may have a thickness of about 2-5 nm. The coating of hexagonal BN 406 may be initiated from the metal catalyst droplets 404. The hexagonal BN 406 may form a BNNT coating on the CNTs 402. The pellicle 400 of FIG. 4B comprises a CNT-h-BN or CNT-BNNT nanocomposite structure.

FIG. 4C illustrates the hexagonal BN 406 coated CNTs 402 having a conformal coating of CNTs 408 disposed thereon. The conformal coating of CNTs 408 is disposed on the hexagonal BN 406 coating, and may be initiated from the metal catalyst droplets 404. Since the hexagonal BN 406 has a same or similar lattice structure as the CNTs 408, the growth of the CNTs 408 follows the lattice of the hexagonal BN 406. The conformal coating of CNTs 408 may have a thickness of about 2-5 nm. The pellicle 400 of FIG. 4C comprises a CNT-h-BN-CNT or CNT-BNNT-CNT nanocomposite structure.

FIG. 4D illustrates the CNT 408 and h-BN 406 coated CNTs 402 having a second conformal coating of h-BN 410 disposed thereon. The second conformal coating of h-BN 410 is disposed on the coating of CNTs 408, and may be initiated from the metal catalyst droplets 404. The second conformal coating of h-BN 410 may have a thickness of about 2-5 nm. The second conformal coating of h-BN 410 may form a BNNT coating on the coating of CNTs 408. Following the second conformal coating of h-BN 410, each h-BN-CNT-h-BN coated CNT 402 (or BNNT-CNT-BNNT coated CNT 402) may be spaced from adjacent coated CNTs 402. As such, the pellicle 400 may have spaces or gaps therethrough.

The pellicle 400 of FIG. 4D comprises a CNT-h-BN-CNT-h-BN or CNT-BNNT-CNT-BNNT nanocomposite structure. The CNT-h-BN-CNT-h-BN or CNT-BNNT-CNT-BNNT nanocomposite structures may have a total thickness of about 30 nm or less and a length or width of about 30 nm. In one embodiment, graphene layers are grown and utilized instead of CNTs. As such, the pellicle 400 may have a graphene-BN-graphene-BN nanocomposite structure.

FIG. 4E illustrates an exemplary multilayer pellicle 420. The pellicle 420 is planar sheet or membrane of CNTs coated in BN. The multilayer pellicle 420 may comprise a CNT-h-BN-CNT-h-BN or CNT-BNNT-CNT-BNNT nanocomposite structure. The multilayer pellicle 420 comprises the plurality of metal catalyst droplets 404, the first CNTs 402 initiated from the metal catalyst droplets 404, an h-BN coating 406 disposed on the first CNTs 402, a second CNT coating 408 disposed on the h-BN coating 406, and a second h-BN coating 410 disposed on the second CNT coating 408. Each coating of the multilayer pellicle 420 is grown sequentially, as described in FIGS. 4A-4D. The first CNTs 402 form a planar sheet or membrane that serves as the base for the subsequent coatings. The number of coatings or multilayers in the multilayer pellicle 420 can improve the thermomechanical strength of the multilayer pellicle 420. Additionally, each of the layers or coatings of the multilayer pellicle 420 are transparent in UV light, and may have an EUV transmission of about 90% or greater. The multilayer pellicle 420 is non-reactive in a hydrogen radical environment due to the h-BN or BNNT coatings.

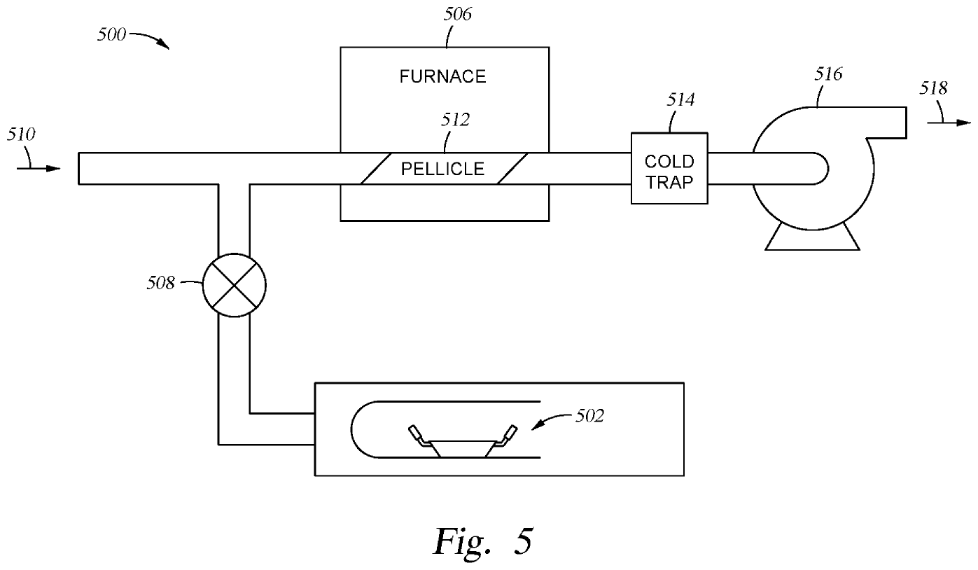

FIG. 5 illustrates a tool schematic 500 for forming a nanocomposite pellicle 512, according to one embodiment. The tool schematic 500 may be used to form a CNT-BN-BNNT pellicle, a CNT-h-BN-CNT-h-BN pellicle, or a CNT-BNNT-CNT-BNNT pellicle, as shown in FIGS. 3A-3C and FIGS. 4A-4E. The tool schematic 500 may comprise a heating belt 504, a valve 508, a furnace 506, a cold trap 514, a pump 516, and an exhaust 518.

A precursor 502 may be heated in the heating belt 504 at a first temperature (T₁) of about 60 to about 150 degrees Celsius, such as about 90 to 110 degrees Celsius. The precursor 502 may comprise ammonia borane, borazane, borazine, decaborane, or any other compound capable of having the same or similar lattice structure as graphene and comprising boron and nitrogen. For example, heating a precursor 502 comprising ammonia borane to the first temperature causes the ammonia borane to dissociate to borazine, which has the same lattice structure as graphene and CNTs.

The heated precursor 502 may be transferred to a furnace 506 using a valve 508 and a carrier gas 510. The carrier gas 510 may be hydrogen (H₂) gas. The heated precursor 502 may then be processed in the furnace 506 with a graphene membrane at a second temperature (T₂) of about 800-1200 degrees Celsius, such as about 800-1000 degrees Celsius, for about 10-60 minutes, such as about 20-40 minutes, at a pressure of about 0.5-2 T, such as about 1 T. Processing the heated precursor 502 in the furnace 506 forms a BN coating on the graphene membrane to form the nanocomposite pellicle 512. The nanocomposite pellicle 512 comprising a planar sheet of CNTs coated in at least one coating of BN, such as the pellicle 300 of FIG. 3C or the pellicle 420 of FIG. 4E.

Processing the heated precursor 502 in the furnace 506 may initiate the growth of a plurality of CNTs from the graphene membrane. Processing the heated precursor 502 in the furnace 506 may form a BN coating on the CNTs and may simultaneously form one or more BNNTs on the CNTs to form a CNT-BN-BNNT nanocomposite pellicle 512. A second graphene membrane may be processed in the furnace 506 to sequentially coat the BN coating in a CNT coating. The CNT coating disposed on the BN coating may then sequentially be coated in second BN coating, forming a graphene-BN-graphene-BN, CNT-h-BN-CNT-h-BN, or CNT-BNNT-CNT-BNNT nanocomposite pellicle.

Coating carbon nanotubes with boron nitride to form a pellicle results in a UV transparent pellicle having increased thermomechanical strength. Moreover, pellicles formed of carbon nanotubes coated in boron nitride are non-reactive in hydrogen radical environments. Since pellicles comprising boron nitride coated carbon nanotubes are non-reactive in hydrogen radical environments, the lifespan of the pellicle may be increased, as the pellicle is not susceptible to being etched by active hydrogen radicals. Increasing the lifespan of the pellicle may reduce overall costs in the lithography system, as the system will not need replacement pellicles as often.

Furthermore, pellicles formed of carbon nanotubes coated in boron nitride may have an EUV transmission of about 90% or greater, a deep UV transmission of about 80% or greater, an EUV transmission uniformity of less than 0.04%, and low EUV reflectivity, such as having a noise level of about 0.001% and an EUV scattering of less than about 0.25%.

While the foregoing is directed to embodiments of the present disclosure, other and further embodiments of the disclosure may be devised without departing from the basic scope thereof, and the scope thereof is determined by the claims that follow.

What is claimed is:

1. A pellicle for an extreme ultraviolet lithography system, comprising:
a plurality of carbon nanotubes arranged in a planar sheet; and
a first boron nitride coating disposed on each of the plurality of carbon nanotubes.

2. The pellicle of claim 1, further comprising a plurality of boron nitride nanotubes.

3. The pellicle of claim 1, further comprising a carbon nanotube coating disposed on the first boron nitride coating.

4. The pellicle of claim 3, further comprising a second boron nitride coating disposed on the carbon nanotube coating.

5. The pellicle of claim 4, wherein the first boron nitride coating forms a first boron nitride nanotube disposed around the plurality of carbon nanotubes.

6. The pellicle of claim 5, wherein the second boron nitride coating forms a second boron nitride nanotube disposed around the plurality of carbon nanotubes.

7. The pellicle of claim 4 wherein the first boron nitride coating comprises hexagonal boron nitride.

8. The pellicle of claim 7, wherein the second boron nitride coating comprises hexagonal boron nitride.

9. A method of forming pellicle, comprising:
forming a plurality of carbon nanotubes arranged in a planar sheet;
coating the plurality of carbon nanotubes with boron nitride; and
forming a plurality of boron nitride nanotubes, wherein the plurality of boron nitride nanotubes are formed simultaneously as the plurality of carbon nanotubes are coated with boron nitride.

10. The method of claim 9, wherein the plurality of nanotubes are formed using a plurality of metal catalyst droplets.

11. The method of claim 10, wherein the plurality of metal catalyst droplets comprises iron, nickel, or nickel iron.

12. The method of claim 10, wherein the plurality of boron nitride nanotubes are formed using one or more excess metal catalyst droplets of the plurality of metal catalyst droplets that are uncovered by the plurality of carbon nanotubes.

13. The method of claim 9, wherein the plurality of carbon nanotubes are coated with boron nitride at a temperature between about 800 to 1200 degrees Celsius.

14. A method of forming pellicle, comprising:
forming a plurality of carbon nanotubes arranged in a planar sheet;
coating the plurality of carbon nanotubes with a first layer of boron nitride;
coating the first layer of boron nitride with a carbon nanotube layer; and
coating the carbon nanotube layer with a second layer of boron nitride.

15. The method of claim 14, wherein the plurality of nanotubes are formed using a plurality of metal catalyst droplets.

16. The method of claim 15, wherein the plurality of metal catalyst droplets comprises iron, nickel, or nickel iron.

17. The method of claim 15, wherein the plurality of metal catalyst droplets are dispersed in a particular layout.

18. The method of claim 14, wherein the first layer of boron nitride comprises hexagonal boron nitride.

19. The method of claim 14, wherein the first layer of boron nitride is a first layer of boron nitride carbon nanotubes.

20. The method of claim 14, wherein the second layer of boron nitride is a second layer of boron nitride carbon nanotubes.
